(19) United States
(12) Patent Application Publication
(10) Pub. No.: US 2024/0387769 A1
(43) Pub. Date: Nov. 21, 2024

(54) METHOD FOR PRODUCING A GROWTH SUBSTRATE, GROWTH SUBSTRATE, AND METHOD FOR PRODUCING A PLURALITY OF OPTOELECTRONIC SEMICONDUCTOR CHIPS

(71) Applicant: ams-OSRAM International GmbH, Regensburg (DE)

(72) Inventors: Hans-Jürgen Lugauer, Sinzing (DE); Adrian Stefan Avramescu, Regensburg (DE); Marc Hoffmann, Regensburg (DE); Viola Miran Kueller, Barbing (DE); Humberto Foronda, Regensburg (DE); Christian Brandl, Sünching (DE)

(21) Appl. No.: 18/692,226

(22) PCT Filed: Aug. 30, 2022
(86) PCT No.: PCT/EP2022/074082

§ 371 Date: Mar. 14, 2024

(30) Foreign Application Priority Data
Sep. 21, 2021 (DE) 10 2021 124 366.1

(51) Int. Cl. H01L 33/00

(52) U.S. Cl. CPC H01L 33/0093

(57) ABSTRACT

In an embodiment a method for producing a growth substrate includes providing a polycrystalline substrate having a nitride compound semiconductor material, applying at least one surface layer onto a main surface of the polycrystalline substrate, wherein the at least one surface layer comprises a nitride compound semiconductor material, and wherein the at least one surface layer is configured for epitaxial growth of an epitaxial semiconductor layer sequence, and high-temperature annealing of the polycrystalline substrate with the at least one surface layer applied thereto.

### CROSS-REFERENCE TO RELATED APPLICATIONS

This patent application is a national phase filing under section 371 of PCT/EP2022/074082, filed Aug. 30, 2022, which claims the priority of German patent application 102021124366.1, filed Sep. 21, 2021, each of which is incorporated herein by reference in its entirety.

### TECHNICAL FIELD

A method for producing a growth substrate, a growth substrate and a method for producing a plurality of optoelectronic semiconductor chips are disclosed.

### SUMMARY

Embodiments provide a method for producing a growth substrate, a growth substrate and a method for producing a plurality of optoelectronic semiconductor chips, that exhibit improved thermal tensioning properties.

According to at least one embodiment of the method for producing a growth substrate, a polycrystalline substrate is first provided.

The polycrystalline substrate comprises a plurality of small single crystals. In particular, the polycrystalline substrate is not a monocrystalline substrate. For example, the polycrystalline substrate is manufactured using ceramic processes, in particular by sintering a powder of small single crystals. In this process, a powder of small single crystals is heated under increased pressure and formed into the shape of the polycrystalline substrate, whereby the single crystals melt on their surface and grow together. This results in a solidified polycrystalline substrate, which preferably has a diameter of at least 150 millimeters. In particular, the polycrystalline substrate may have cavities between the small single crystals that have grown together.

According to at least one further embodiment, the polycrystalline substrate comprises a nitride compound semiconductor material.

Nitride compound semiconductor materials are compound semiconductor materials that contain nitrogen, such as materials from the system InₓAl_{y}Ga_{1-x-y}N with 0≤ x≤1, 0≤ y≤1 and x+y≤1. This material does not necessarily have to have a mathematically exact composition according to the above formula. Rather, it can comprise one or more dopants as well as additional components, for example. For the sake of simplicity, however, the above formula only contains the essential components of the crystal lattice (Al, Ga, In, N), even if these can be partially replaced and/or supplemented by small amounts of other substances, for example boron or scandium.

The polycrystalline substrate comprises aluminum nitride or preferably consists of aluminum nitride.

According to at least one further embodiment of the method for producing a growth substrate, at least one surface layer is applied onto a main surface of the polycrystalline substrate. The main surface of the polycrystalline substrate refers to a surface intended for epitaxial growth of an epitaxial semiconductor layer sequence. The at least one surface layer comprises a nitride compound semiconductor material. In particular, a surface of the at least one surface layer facing away from the main surface of the polycrystalline substrate is configured for the epitaxial growth of an epitaxial semiconductor layer sequence.

For example, the surface layer comprises the same nitride compound semiconductor material as the polycrystalline substrate. In particular, the surface layer is deposited directly on the main surface of the polycrystalline substrate by sputtering, chemical vapor deposition or atomic layer deposition. The surface layer has, for example, a polycrystalline structure of microcrystallites and is configured, in particular, to level out unevenness in the main surface of the polycrystalline substrate. This unevenness is caused, for example, by cavities between the single crystals of the polycrystalline substrate, which are fused together by sintering. A smooth surface of the surface layer is advantageous in order to epitaxially grow a low-defect epitaxial semiconductor layer sequence on it.

The surface layer has a thickness between 10 nanometers and five micrometers, for example. Preferably, the surface layer has a thickness between 20 nanometers and 500 nanometers. A thickness here and in the following refers to an extension of the surface layer in a direction parallel to the surface normal of the main surface of the polycrystalline substrate.

According to at least one further embodiment of the method for producing a growth substrate, the polycrystalline substrate with the at least one surface layer applied thereto is subjected to high-temperature annealing.

During high-temperature annealing, the surface layer together with the polycrystalline substrate is tempered or baked at a sufficiently high temperature for a longer period of time. For example, the temperature during tempering or baking is between 700° Celsius and 1800° Celsius, inclusive. The tempering or baking can take place over a period of between one hour and 24 hours, for example. During high-temperature annealing, the microcrystallites in the surface layer realign themselves, for example by reducing an inclination and twisting of the microcrystallites relative to each other. In particular, the microcrystallites can grow together to form a homogeneous, low-defect monocrystalline surface layer. A monocrystalline surface layer produced by high-temperature annealing is particularly suitable for epitaxial growth of a low-defect epitaxial semiconductor layer sequence.

Alternatively, columnar crystallites of high quality can be formed in the surface layer by three-dimensional crystal growth due to different process parameters during high-temperature annealing, for example. In this case, a further surface layer, for example a buffer layer, can be deposited on the surface layer after high-temperature annealing in order to obtain a homogeneous, monocrystalline surface with a smooth surface morphology and a reduced defect density. The buffer layer can be deposited on the high-temperature annealed surface layer, for example by chemical vapor deposition or other epitaxial growth processes.

According to an embodiment of the method, the high-temperature annealing comprises a heating phase, a baking phase and a cooling phase. During the heating phase, the temperature of the polycrystalline substrate with the at least one surface layer applied thereto is increased until a baking temperature is reached. The baking temperature is, for example, between 700° C. and 1800° C., inclusive. In particular, the baking temperature is lower than a melting temperature of the polycrystalline substrate and/or the at least one surface layer.

During the baking phase, the polycrystalline substrate with the at least one surface layer applied thereto is baked at the baking temperature over a longer period of time. For example, the period of the baking phase is between one hour and 24 hours, inclusive. During the baking phase, the baking temperature is preferably kept constant. The baking temperature can also be changed as a function of time during the baking phase.

During the cooling phase, the polycrystalline substrate with the at least one surface layer applied thereto is cooled to room temperature, for example. In particular, a period of the cooling phase and a temperature profile over time during the cooling phase are selected in such a way that the at least one surface layer has the lowest possible defect density.

For example, the publication H. Miyake et al, Journal of Crystal Growth 456 (2016) 155-159, describes a high-temperature annealing in a different context and is hereby incorporated by reference.

According to an embodiment, the method for producing a growth substrate comprises the following steps:
providing a polycrystalline substrate comprising a nitride compound semiconductor material,
applying at least one surface layer onto a main surface of the polycrystalline substrate, wherein
the at least one surface layer comprises a nitride compound semiconductor material, and
the at least one surface layer is configured for epitaxial growth of an epitaxial semiconductor layer sequence,
high-temperature annealing of the polycrystalline substrate with the at least one surface layer applied thereto.

Optoelectronic semiconductor layer sequences based on aluminum gallium nitride, which are configured to emit electromagnetic radiation in the UV spectral range with wavelengths between 100 nanometers and 360 nanometers, are grown epitaxially on monocrystalline sapphire substrates, for example. Due to different thermal expansion coefficients of, for example, aluminum (gallium) nitride and the sapphire substrate, significant mechanical stresses can occur during cooling after the epitaxial growth process, which lead in particular to a strong warping of the sapphire substrate. This warping can be so large that a subsequent processing of the epitaxial semiconductor layer sequence into optoelectronic semiconductor chips is made more difficult or even prevented. For example, a continuous sharp exposure of a photomask on the epitaxial semiconductor layer sequence may not be possible due to the warping of the sapphire substrate. Furthermore, cracks can occur in the epitaxial semiconductor layer sequence due to the mechanical tension when the sapphire substrate is detached from the epitaxial semiconductor layer sequence, for example during the manufacturing of thin-film chips. Similar problems can occur with growth substrates comprising other materials, such as silicon carbide growth substrates. For the sake of simplicity, the following discussion is limited to sapphire substrates, but also applies to other growth substrates.

These problems become more pronounced the larger a diameter of the sapphire substrate is. In particular, a distance between a highest and a lowest point of a surface of the sapphire substrate caused by the warping of the sapphire substrate scales quadratically with the diameter of the sapphire substrate. Due to this warping, optoelectronic semiconductor chips based on aluminum gallium nitride, for example, can only be manufactured on sapphire substrates with a diameter of 2 inches, and to a limited extent also on sapphire substrates with a diameter of up to 4 inches.

Lateral thermal gradients in the sapphire substrate pose a further problem. These gradients arise due to the warping of the sapphire substrate at the high production temperatures of approximately 1000° Celsius for the epitaxial growth of aluminum gallium nitride, for example. The thermal gradients can, for example, lead to fracture of the sapphire substrate. In particular, this problem occurs for sapphire substrates with a diameter of at least 4 inches. To prevent the sapphire substrate from breaking, a thicker sapphire substrate can be used, for example. However, this can be associated with additional, increased effort in the processing of the optoelectronic semiconductor chips, for example in the event of mechanical detachment of the sapphire substrate.

One idea of the method for producing a growth substrate described herein is to provide a growth substrate adapted for the epitaxy of nitride compound semiconductor materials based on a low-cost polycrystalline substrate. In particular, the thermal expansion coefficient of the growth substrate is adapted to a thermal expansion coefficient of the optoelectronic semiconductor layer sequence. Furthermore, a structure of the crystal lattice of the growth substrate can also be adapted to a structure of the crystal lattice of the epitaxial semiconductor layer sequence. As a result, for example, low-defect optoelectronic semiconductor layer sequences made of nitride compound semiconductor materials, in particular aluminum gallium nitride or indium gallium nitride, can be grown epitaxially on inexpensive growth substrates with diameters of at least 150 millimeters.

By contrast, monocrystalline growth substrates made of aluminum nitride are very expensive and are not commercially available with diameters of at least 150 millimeters. Polycrystalline substrates based on aluminum nitride or silicon carbide produced using ceramic processes are not suitable for direct epitaxial growth of epitaxial semiconductor layer sequences due to their polycrystalline structure and the associated irregular surface morphology.

The method for producing a growth substrate described herein is based, among other things, on the realization that inexpensive polycrystalline substrates with a high-temperature annealed surface layer applied thereto are suitable as growth substrates for the epitaxy of optoelectronic semiconductor layer sequences. In particular, a low-defect, monocrystalline surface layer can be produced on the polycrystalline substrate by high-temperature annealing, on which a low-defect semiconductor layer sequence can subsequently be grown epitaxially. In particular, by adapting the thermal expansion coefficient of the growth substrate to the thermal expansion coefficient of the epitaxial semiconductor layer sequence, mechanical stresses which lead to a warping of the growth substrate during cooling after the epitaxial growth process, can be reduced or avoided. As a result, in particular optoelectronic semiconductor layer sequences comprising aluminum gallium nitride can be grown epitaxially at low cost on large growth substrates with diameters of at least 150 millimeters. In particular, no additional measures are required in epitaxy and chip processing to reduce the warping of the growth substrate.

According to at least one further embodiment of the method for producing a growth substrate, the polycrystalline substrate comprises aluminum nitride and the at least one surface layer comprises aluminum nitride or indium gallium nitride.

According to at least one further embodiment of the method for producing a growth substrate, the at least one surface layer is applied by sputtering or atomic layer deposition. The surface morphology of the main surface of the polycrystalline substrate, as well as the process parameters during high-temperature annealing, affect a crystal quality of the surface layer. Depending on these parameters, a surface layer that is applied to the polycrystalline substrate either by sputtering or by atomic layer deposition can lead to a higher crystal quality of the surface layer after high-temperature annealing.

According to at least one further embodiment of the method for producing a growth substrate, a further surface layer is applied by metal-organic chemical vapor deposition (MOCVD) or by sputtering before the high-temperature annealing.

In order to improve the quality of the surface of the growth substrate for the epitaxial growth of the epitaxial semiconductor layer sequence, a further surface layer can be applied onto the first surface layer before the high-temperature annealing. In particular, a further surface layer can be applied onto a sputtered surface layer by means of metal-organic chemical vapor deposition. Alternatively, a further surface layer can be applied by sputtering, for example, onto a surface layer that is applied by atomic layer deposition, physical vapor deposition, electron beam epitaxy, molecular beam epitaxy or liquid phase epitaxy. The additional surface layer leads to improved reorientation of the microcrystallites in the previously applied at least one surface layer during high-temperature annealing, for example.

According to at least one further embodiment of the method for producing a growth substrate, the at least one surface layer is planarized by a chemical-mechanical polishing process after the high-temperature annealing. A particularly smooth surface of the growth substrate is advantageous for the epitaxial growth of the epitaxial semiconductor layer sequence on the growth substrate. Unevenness in the surface of the growth substrate, which may be present after high-temperature annealing, is removed by a polishing process, for example.

According to at least one further embodiment of the method for producing a growth substrate, a buffer layer is epitaxially grown on the surface layer after high-temperature annealing.

The buffer layer preferably comprises the same semiconductor material as the epitaxial semiconductor layer sequence, which is subsequently grown epitaxially on the growth substrate. The buffer layer is applied, for example, by chemical vapor deposition, preferably by metal-organic vapor phase epitaxy (MOVPE). In particular, the buffer layer is configured to obtain a closed, homogeneous, monocrystalline surface of the growth substrate with a smooth surface morphology and reduced defect density. Furthermore, the buffer layer can be configured to adapt the structure of the crystal lattice of the growth substrate to the structure of the crystal lattice of the epitaxial semiconductor layer sequence. In particular, the buffer layer is advantageously applied to a sputtered surface layer which comprises columnar crystallites of high crystal quality after high-temperature annealing.

According to at least one further embodiment of the method for producing a growth substrate, the buffer layer comprises aluminum nitride or indium gallium nitride.

Further, a growth substrate is disclosed. All features disclosed for the method for producing a growth substrate are also disclosed for the growth substrate. Conversely, all features disclosed for the growth substrate are also disclosed for the method for producing a growth substrate.

According to one embodiment, the growth substrate comprises a polycrystalline substrate comprising a nitride compound semiconductor material and having a main surface.

In particular, the polycrystalline substrate is manufactured by a ceramic process, for example by sintering a powder of small single crystals. Preferably, the polycrystalline substrate has a diameter of at least 150 mm. If an adjustment of the thermal expansion coefficients of the growth substrate and the epitaxial semiconductor layer sequence to be grown thereon takes place, a thickness of the polycrystalline substrate of at most 1000 micrometers is sufficient. For example, the polycrystalline substrate comprises aluminum nitride or consists of aluminum nitride. The main surface of the polycrystalline substrate can have a rough surface morphology, which is created, for example, by small cavities between the small single crystals that have fused together as a result of sintering.

According to at least one further embodiment, the growth substrate comprises a surface layer. The surface layer comprises a nitride compound semiconductor material and is arranged on the main surface of the polycrystalline substrate. In particular, the surface layer is configured for epitaxial growth of an epitaxial semiconductor layer sequence.

In particular, the surface layer has a smooth surface morphology and is preferably formed as a homogeneous, low-defect, monocrystalline layer. A smooth, monocrystalline surface of the surface layer is advantageously suitable for growing a low-defect, epitaxial semiconductor layer sequence thereon. Alternatively, the surface layer can comprise columnar crystallites of high crystal quality to which a further buffer layer is applied that comprises the same semiconductor material as the surface layer, for example. The buffer layer forms a closed, homogeneous layer with a smooth surface morphology and is applied to the surface layer using, for example, an epitaxial growth process. The thickness of the surface layer is, for example, between 10 nanometers and five micrometers, inclusive.

According to an embodiment, the growth substrate comprises:
a polycrystalline substrate comprising a nitride compound semiconductor material and having a main surface, and
at least one surface layer comprising a nitride compound semiconductor material and arranged on the main surface of the polycrystalline substrate, the surface layer being configured for epitaxial growth of an epitaxial semiconductor layer sequence.

According to at least one further embodiment of the growth substrate, the polycrystalline substrate comprises aluminum nitride.

Epitaxial semiconductor layer sequences that are configured for generating electromagnetic radiation in the UV spectral range with wavelengths between 100 nanometers and 360 nanometers comprise, in particular, aluminum gallium nitride. A growth substrate with an adapted thermal expansion coefficient is particularly advantageous for the epitaxial growth of such semiconductor layer sequences. As a result, mechanical stresses caused by cooling after the epitaxial growth process can be reduced or avoided. Thus, the epitaxial growth process can be carried out cost-effectively on larger growth substrates. In particular, a growth substrate comprising or consisting of aluminum nitride is particularly suitable for the epitaxial growth of semiconductor layer sequences comprising aluminum gallium nitride. In contrast to monocrystalline growth substrates made of aluminum nitride, the growth substrate described here, which is based on a polycrystalline substrate, can be produced particularly cost-effectively and easily with diameters of at least 150 mm.

According to at least one further embodiment of the growth substrate, the at least one surface layer comprises aluminum nitride or indium gallium nitride.

A surface layer comprising aluminum nitride is particularly suitable for the epitaxial growth of an epitaxial semiconductor layer sequence comprising aluminum gallium nitride and that is configured for emitting electromagnetic radiation in the UV spectral range. A surface layer comprising indium gallium nitride is preferably suitable for the epitaxial growth of an epitaxial semiconductor layer sequence comprising indium gallium nitride and that is configured, for example, to generate electromagnetic radiation in the near-UV to blue spectral range. As a result, the thermal expansion coefficient of the polycrystalline substrate and the structure of the crystal lattice of the surface layer can be adapted to an epitaxial semiconductor layer sequence that is to be epitaxially grown on the surface layer.

According to at least one further embodiment of the growth substrate, the at least one surface layer has a thickness between 10 nanometers and 5 micrometers, inclusive.

In particular, the surface layer has a thickness such that the unevenness in the main surface of the polycrystalline substrate, which is formed by cavities between the single crystals of the polycrystalline substrate, for example, is at least evened out or covered by the surface layer.

According to at least one further embodiment of the growth substrate, the polycrystalline substrate has a diameter of at least 100 millimeters and a maximum thickness of 1000 micrometers.

In contrast to monocrystalline growth substrates made of aluminum nitride, polycrystalline substrates comprising aluminum nitride or consisting of aluminum nitride can be produced easily and cost-effectively with a diameter of at least 100 millimeters. By adapting the thermal expansion coefficient of the growth substrate to the thermal expansion coefficient of the epitaxial semiconductor layer sequence to be grown on it, thermal stress problems after the epitaxial growth of the epitaxial semiconductor layer sequence are reduced or avoided. As a result, warping of the growth substrate due to cooling after the epitaxial growth process is reduced or avoided. In contrast to the epitaxial growth of an epitaxial semiconductor layer sequence on a growth substrate whose thermal expansion coefficient is not adapted, a growth substrate with a smaller thickness can thus be used. In particular, the polycrystalline substrate has a maximum thickness of 1000 micrometers.

Further, a method for producing a plurality of optoelectronic semiconductor chips is disclosed.

All features disclosed for the growth substrate are also disclosed for the method for producing a plurality of optoelectronic semiconductor chips. Conversely, all features disclosed for the method for producing a plurality of optoelectronic semiconductor chips are also disclosed for the growth substrate.

According to at least one embodiment of the method for producing a plurality of optoelectronic semiconductor chips, a growth substrate is first provided, wherein the growth substrate comprises a polycrystalline substrate and at least one surface layer applied thereto. In particular, the growth substrate comprises features of the growth substrate described above.

According to at least one further embodiment of the method for producing a plurality of optoelectronic semiconductor chips, an epitaxial semiconductor layer sequence with an active layer for generating electromagnetic radiation is epitaxially grown on the growth substrate in a next step. In particular, the epitaxial semiconductor layer sequence comprises a nitride compound semiconductor material.

Preferably, the growth substrate comprises the same nitride compound semiconductor material as the epitaxial semiconductor layer sequence. This ensures an adaptation of the thermal expansion coefficients. To adapt the structure of the crystal lattice of the epitaxial semiconductor layer sequence to the structure of the crystal lattice of the growth substrate, the surface layer of the growth substrate preferably comprises the same semiconductor material as the epitaxial semiconductor layer sequence.

The active layer comprises, for example, at least one p-doped semiconductor region and at least one n-doped semiconductor region, which form a light-emitting diode.

According to at least one further embodiment of the method for producing a plurality of optoelectronic semiconductor chips, connecting contacts for a plurality of optoelectronic semiconductor chips are applied to the epitaxial semiconductor layer sequence in a next step.

The application of the connecting contacts comprises at least the application of an electrically conductive layer, as well as, for example, photolithographic processes and etching processes for structuring the connecting contacts. In addition, further process steps can be carried out for structuring the individual semiconductor chips and for electrically contacting the active layer.

According to at least one further embodiment of the method for producing a plurality of optoelectronic semiconductor chips, a carrier substrate is applied to the connecting contacts. In particular, the carrier substrate is configured for electrically contacting the optoelectronic semiconductor chips.

According to at least one further embodiment of the method for producing a plurality of optoelectronic semiconductor chips, the growth substrate is detached from the epitaxial semiconductor layer sequence.

In particular, during manufacturing of optoelectronic semiconductor chips that are configured to generate electromagnetic radiation in the UV spectral range, it is advantageous to detach the growth substrate from the epitaxial semiconductor layer sequence, as many growth substrates are not transparent to electromagnetic radiation in the UV spectral range that is generated during operation. For example, polycrystalline aluminum nitride can comprise impurities that turn the polycrystalline substrate non-transparent for UV light. The growth substrate can be detached, for example, by wet chemical etching, dry chemical etching or mechanical polishing. Alternatively, the growth substrate can also be detached by a laser lift-off process or by a chemical lift-off process, whereby the growth substrate is not destroyed and can be re-used if necessary.

According to at least one further embodiment of the method for producing a plurality of optoelectronic semiconductor chips, the optoelectronic semiconductor chips are singulated.

Singulation is carried out, for example, by sawing or by a directed plasma etching process to cut through the epitaxial semiconductor layer sequence and/or the carrier substrate.

According to at least one embodiment, the method for producing a plurality of optoelectronic semiconductor chips comprises the following steps:
providing a growth substrate as described herein,
epitaxial growth of an epitaxial semiconductor layer sequence with an active layer for generating electromagnetic radiation, wherein the epitaxial semiconductor layer sequence comprises a nitride compound semiconductor material,
applying connecting contacts for a large number of optoelectronic semiconductor chips on the epitaxial semiconductor layer sequence,
applying a carrier substrate on the connecting contacts,
detaching the growth substrate from the epitaxial semiconductor layer sequence
singulating the optoelectronic semiconductor chips.

According to at least one further embodiment of the method for producing a plurality of optoelectronic semiconductor chips, the growth substrate is detached up to the at least one surface layer of the growth substrate, wherein the surface layer remains at least partially on the epitaxial semiconductor layer sequence.

A surface layer comprising aluminum nitride can have fewer impurities than, for example, a polycrystalline substrate comprising aluminum nitride. In particular, the surface layer can be transparent to electromagnetic radiation in the UV spectral range, in contrast to the polycrystalline substrate. For this reason, the surface layer can remain at least partially on the epitaxial semiconductor layer sequence. It is therefore not necessary to completely detach the growth substrate including the surface layer. This can prevent damage to the epitaxial semiconductor layer sequence when the growth substrate is detached, for example.

According to at least one further embodiment of the method for producing a plurality of optoelectronic semiconductor chips, the epitaxial semiconductor layer sequence comprises an etch stop layer, wherein the etch stop layer comprises aluminum gallium nitride. In particular, a gallium content of the etch stop layer is at least 5%, preferably at least 40%, and the growth substrate is detached up to the etch stop layer.

The etch stop layer is configured, for example, to be able to precisely stop an etching process for removing the growth substrate. In particular, this enables the growth substrate to be completely detached without damaging the epitaxial semiconductor layer sequence. In particular, the gallium content in the etch-stop layer can be detected during a chemical-mechanical polishing process, for example, which makes it possible to precisely stop the etching process at the etch-stop layer. Alternatively, the etch stop layer can be configured to remove the growth substrate by a laser lift-off process, whereby the etch stop layer decomposes during exposure to light.

Further advantageous embodiments and further developments of the method for producing a growth substrate, of the growth substrate and of the method for producing a plurality of optoelectronic semiconductor chips, become apparent from the exemplary embodiments described in connection with the figures below.

### BRIEF DESCRIPTION OF THE DRAWINGS

FIGS. 1A to 1H show schematic views of different steps of a method for producing a plurality of optoelectronic semiconductor chips according to different exemplary embodiments;

FIGS. 2A to 2C show schematic views of a growth substrate after different steps of a method for producing a growth substrate according to different exemplary embodiments; and

FIGS. 3A to 3C show schematic views of a growth substrate after different steps of a method for producing a growth substrate according to further exemplary embodiments.

Elements that are identical, similar or have the same effect are denoted with the same reference signs in the figures. The figures and the proportions of the elements shown in the figures should not be considered to be true to scale. Rather, individual elements, in particular layer thicknesses, may be shown exaggeratedly large for better visualization and/or understanding.

### DETAILED DESCRIPTION OF ILLUSTRATIVE EMBODIMENTS

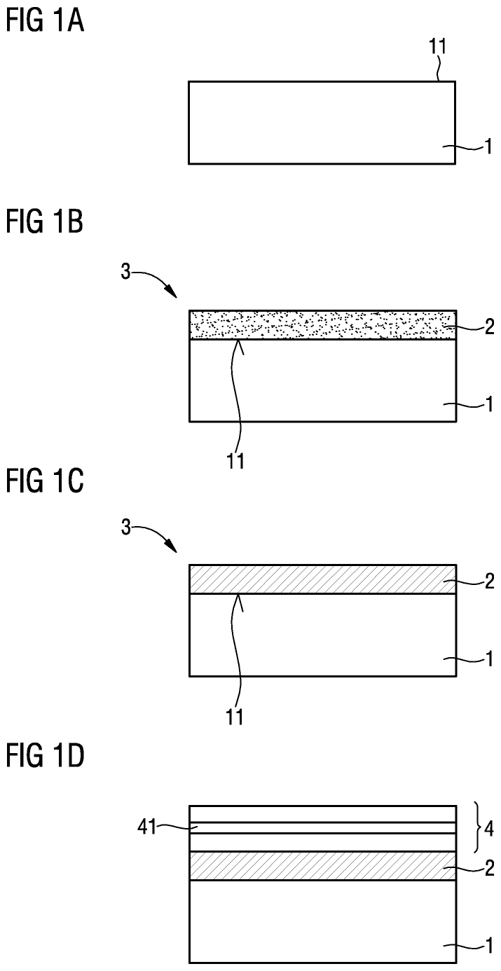

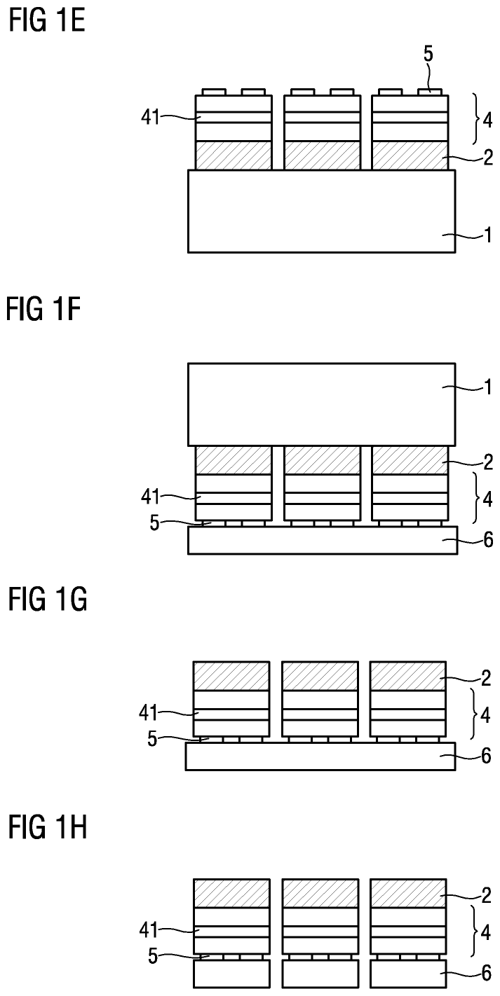

The schematic cross-section in FIG. 1A shows a polycrystalline substrate 1 comprising a main surface 11 and that is provided in a first method step. The polycrystalline substrate 1 comprises aluminum nitride and is produced by sintering a powder of small single crystals comprising aluminum nitride. The polycrystalline substrate 1 has a diameter of at least 150 millimeters and a thickness of up to 1000 micrometers.

FIG. 1B shows a schematic cross-section of the growth substrate 3 after a further method step, wherein a surface layer 2 is applied to the main surface 11 of the polycrystalline substrate 1. The surface layer 2 comprises aluminum nitride and is deposited on the main surface 11 of the polycrystalline substrate 1 by sputtering, atomic layer deposition, physical vapor deposition, or electron beam epitaxy. A thickness of the surface layer 2 is between 20 nanometers and 500 nanometers, inclusive. In particular, the surface layer 2 is thick enough to level out unevenness in the main surface 11 of the polycrystalline substrate 1.

FIG. 1C shows a schematic cross-section of the growth substrate 3 after the high-temperature annealing of the polycrystalline substrate 1 and the surface layer 2 applied thereto. The polycrystalline substrate 1 with the surface layer 2 applied thereto is tempered at a temperature of between 700° C. and 1800° C. for a period of between 1 hour and 24 hours. The high-temperature annealing causes microcrystallites in the surface layer 2 to realign and reorganize into a monocrystalline layer. This gives rise to a homogeneous, relatively low-defect monocrystalline surface layer 2, which is particularly suitable for epitaxial growth of an epitaxial semiconductor layer sequence 4.

FIG. 1D shows a schematic cross-section of the polycrystalline substrate 1, the surface layer 2 and the epitaxial semiconductor layer sequence 4. In particular, after the high-temperature annealing of the polycrystalline substrate 1 with the surface layer 2 applied thereto, an epitaxial semiconductor layer sequence 4 is epitaxially grown on the surface of the surface layer 2. The epitaxial semiconductor layer sequence 4 comprises aluminum gallium nitride and has an active layer 41 for generating electromagnetic radiation in the UV spectral range. In particular, the active layer 41 comprises an n-doped semiconductor region and a p-doped semiconductor region, which form a light-emitting diode.

FIG. 1E shows a schematic cross-section after a further method step, wherein the epitaxial semiconductor layer sequence 4 is structured to form individual optoelectronic semiconductor chips and electrical connecting contacts 5 are applied. The structuring of the semiconductor layer sequence 4 and the application of the electrical connecting contacts 5 is carried out by photolithographic processes and etching of the epitaxial semiconductor layer sequence.

FIG. 1F shows a schematic cross-section after a further method step, wherein the polycrystalline substrate 1 with the surface layer 2 applied thereto and the epitaxial semiconductor layer sequence 4 is transferred to a carrier substrate 6. In particular, the carrier substrate 6 is configured for electrically contacting the optoelectronic semiconductor chips.

FIG. 1G shows a schematic cross-section after a further method step, wherein the polycrystalline substrate 1 is detached. In particular, the polycrystalline substrate 1 is detached from the semiconductor layer sequence 4 such that the surface layer 2 remains at least partially on the epitaxial semiconductor layer sequence 4. Detachment of the polycrystalline substrate 1 is advantageous because polycrystalline aluminum nitride may not be transparent for electromagnetic radiation in the UV spectral range with wavelengths between 100 nanometers and 360 nanometers due to impurities present therein. by contrast, the surface layer 2 has only few impurities and is at least largely transparent to electromagnetic radiation in the UV spectral range.

The polycrystalline substrate 1 is detached, in particular, using a chemical-mechanical polishing process. Alternatively, the polycrystalline substrate 1 can be removed using a dry-chemical or wet-chemical etching process. By removing the polycrystalline substrate 1 only up to the surface layer 2, the epitaxial semiconductor layer sequence 4 is not damaged by the detachment process.

FIG. 1H shows a schematic cross-section of a plurality of optoelectronic semiconductor chips after a singulation step, wherein the carrier substrate 6 is cut through to singulate the optoelectronic semiconductor chips.

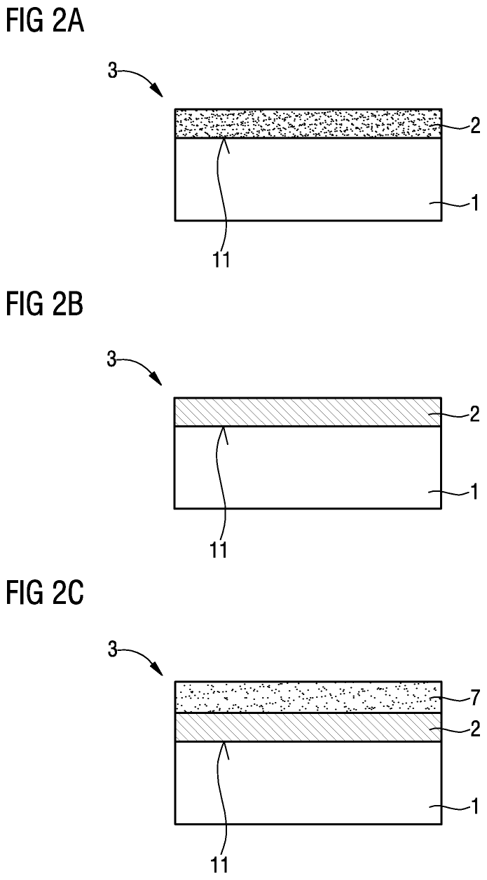

FIGS. 2A to 2C show schematic cross-sections of a growth substrate 3 after different method steps according to different exemplary embodiments.

FIG. 2A shows a polycrystalline substrate 1 analogous to FIG. 1B, which comprises aluminum nitride and has a main surface 11. A surface layer 2 is applied to the main surface 11 of the polycrystalline substrate 1 by sputtering.

FIG. 2B shows a schematic cross-section of the growth substrate 3 after high-temperature annealing of the polycrystalline substrate 1 with the surface layer 2 applied thereto. In contrast to FIG. 1C, no smooth, homogeneous monocrystalline surface layer 2 is formed here after high-temperature annealing due to different process parameters, but rather columnar crystallites of high crystal quality are formed by three-dimensional crystal growth.

FIG. 2C shows a schematic cross-section of the growth substrate 3, wherein a buffer layer 7 is deposited on the surface layer 2 after high-temperature annealing. The buffer layer 7 comprises aluminum nitride and is deposited on the surface layer 2 by an epitaxial growth process, for example by metal-organic vapor phase epitaxy. In particular, the buffer layer 7 is a homogeneous, low-defect monocrystalline layer suitable for epitaxial growth of a low-defect epitaxial semiconductor layer sequence.

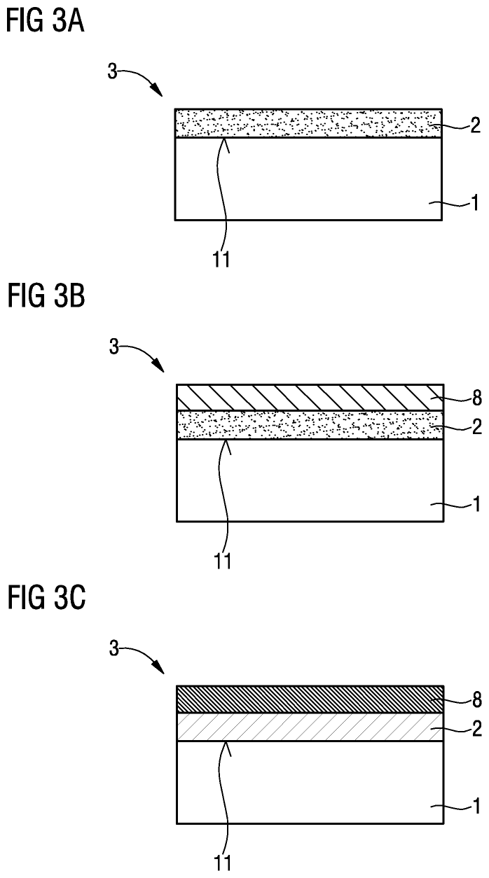

FIGS. 3A to 3C show schematic cross-sections of a growth substrate 3 after different method steps according to further exemplary embodiments.

FIG. 3A shows a growth substrate 3 comprising a polycrystalline substrate 1 with a main surface 11. A first surface layer 2 is deposited on the main surface 11 by sputtering or atomic layer deposition. The polycrystalline substrate 1 and the first surface layer 2 comprise aluminum nitride.

FIG. 3B shows the growth substrate 3 after a further method step in which a further surface layer 8 is applied to the first surface layer 2. In the case of a sputtered first surface layer 2, the further surface layer 8 is deposited on the first surface layer 2 by metal-organic chemical vapor deposition. In the case of a first surface layer 2 deposited on the main surface 11 of the polycrystalline substrate 2 by atomic layer deposition, the further surface layer 8 is deposited on the first surface layer 2 by sputtering. In particular, the further surface layer 8 is configured as an orientation layer and improves an alignment of the microcrystallites in the first surface layer 2 during a subsequent method step in which the growth substrate 3 is annealed at high temperature.

FIG. 3C shows a cross-section of the growth substrate 3 after the high-temperature annealing method step. A homogeneous, smooth, monocrystalline surface 81 of the further surface layer 8 is formed, which is configured for the epitaxial growth of a low-defect epitaxial semiconductor layer sequence 4.

The invention is not restricted to the exemplary embodiments by the description on the basis of said exemplary embodiments. Rather, the invention encompasses any new feature and also any combination of features, which in particular comprises any combination of features in the patent claims, even if this feature or this combination itself is not explicitly specified in the patent claims or exemplary embodiments.

1.-15. (canceled)

16. A method for producing a growth substrate, the method comprising:
providing a polycrystalline substrate comprising a nitride compound semiconductor material;
applying at least one surface layer onto a main surface of the polycrystalline substrate,
wherein the at least one surface layer comprises a nitride compound semiconductor material, and
wherein the at least one surface layer is configured for epitaxial growth of an epitaxial semiconductor layer sequence; and
high-temperature annealing of the polycrystalline substrate with the at least one surface layer applied thereto.

17. The method according to claim 16,
wherein the polycrystalline substrate comprises aluminum nitride, and
wherein the at least one surface layer comprises aluminum nitride or indium gallium nitride.

18. The method according to claim 16, wherein the at least one surface layer is applied by sputtering or atomic layer deposition.

19. The method according to claim 18, further comprising applying a further surface layer by metal-organic chemical vapor deposition or by sputtering before high-temperature annealing.

20. The method according to claim 16, further comprising planarizing the at least one surface layer by a chemical-mechanical polishing process after high-temperature annealing.

21. The method according to claim 16, further comprising epitaxially growing a buffer layer on the surface layer after high-temperature annealing.

22. The method according to claim 21, wherein the buffer layer comprises aluminum nitride or indium gallium nitride.

23. A growth substrate comprising:
a polycrystalline substrate comprising a nitride compound semiconductor material and having a main surface; and
at least one surface layer comprising a nitride compound semiconductor material and arranged on the main surface of the polycrystalline substrate,
wherein the surface layer is configured for epitaxial growth of an epitaxial semiconductor layer sequence, and
wherein the at least one surface layer comprises columnar crystallites.

24. The growth substrate according to claim 23, wherein the polycrystalline substrate comprises aluminum nitride.

25. The growth substrate according to claim 23, wherein the at least one surface layer comprises aluminum nitride or indium gallium nitride.

26. The growth substrate according to claim 23, wherein the at least one surface layer has a thickness between 10 nanometers and 5000 nanometers, inclusive.

27. The growth substrate according to claim 23, wherein the polycrystalline substrate has a diameter of at least 100 millimeters and a maximum thickness of 1000 micrometers.

28. A method for producing a plurality of optoelectronic semiconductor chips, the method comprising:
providing the growth substrate according to claim 23;
epitaxially growing the epitaxial semiconductor layer sequence with an active layer for generating electromagnetic radiation, wherein the epitaxial semiconductor layer sequence comprises a nitride compound semiconductor material;
applying connecting contacts for the plurality of optoelectronic semiconductor chips on the epitaxial semiconductor layer sequence;
applying a carrier substrate on the connecting contacts;
detaching the growth substrate from the epitaxial semiconductor layer sequence; and
singulating the optoelectronic semiconductor chips.

29. The method according to claim 28, wherein the growth substrate is detached up to the at least one surface layer of the growth substrate, and wherein the surface layer remains at least partially on the epitaxial semiconductor layer sequence.

30. The method according to claim 28,
wherein the epitaxial semiconductor layer sequence comprises an etch stop layer,
wherein the etch stop layer comprises aluminum gallium nitride,
wherein a gallium content of the etch stop layer is at least 5%, and
wherein the growth substrate is detached up to the etch stop layer.
